(19) United States
(12) Patent Application Publication
(10) Pub. No.: US 2025/0087584 A1
(43) Pub. Date: Mar. 13, 2025

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Dohyung KIM, Suwon-si (KR); Chulhae PARK, Suwon-si (KR); Younghwan SON, Suwon-si (KR); Sukkang SUNG, Suwon-si (KR)

(73) Assignee: Samsung Electronics Co., Ltd., Suwon-si (KR)

(21) Appl. No.: 18/666,962

(22) Filed: May 17, 2024

(30) Foreign Application Priority Data
Sep. 8, 2023 (KR) 10-2023-0119430

(51) Int. Cl. H01L 23/528; H01L 23/522; H01L 25/065; H10B 41/27; H10B 41/35; H10B 43/27; H10B 43/35; H10B 80/00

(52) U.S. Cl. CPC H01L 23/5283; H01L 23/5226; H01L 25/0652; H10B 41/27; H10B 41/35; H10B 43/27; H10B 43/35; H10B 80/00; H01L 2225/06506

(57) ABSTRACT

A semiconductor device includes a first semiconductor structure including, circuit devices on a substrate, a lower interconnection structure, and a capacitor structure on a same level as a level of at least a portion of the lower interconnection structure, and a second semiconductor structure on the first semiconductor structure and including a plurality of memory cells arranged three-dimensionally. The lower interconnection structure includes a lower contact, a lower line on the lower contact, an upper contact on the lower line, and an upper line on the upper contact. The capacitor structure includes first electrode structures extending in a first direction and spaced apart from each other in a second direction intersecting the first direction, second electrode structures positioned alternately alongside the first electrode structures and spaced apart from each other in the second direction, and dielectric layers between the first electrode structures and the second electrode structures.

### CROSS-REFERENCE TO RELATED APPLICATION(S)

This application claims benefit of priority to Korean Patent Application No. 10-2023-0119430 filed on Sep. 8, 2023 in the Korean Intellectual Property Office, the disclosure of which is incorporated herein by reference in its entirety.

### BACKGROUND

Various example embodiments relate to a semiconductor device and a data storage system including the same.

A semiconductor device able to store high-capacity data in a data storage system requiring data storage has been necessary. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested.

### SUMMARY

Various example embodiments provide a semiconductor device having improved electrical properties and reliability, which may be easily manufactured.

Various example embodiments provide a data storage system including a semiconductor device having improved electrical properties and reliability, which may be easily manufactured.

According to various example embodiments, a semiconductor device includes a first semiconductor structure including a substrate, circuit devices on the substrate, a lower interconnection structure electrically connected to the circuit devices, and a capacitor structure on a same level as a level of at least a portion of the lower interconnection structure, and a second semiconductor structure on the first semiconductor structure and including a plurality of memory cells arranged three-dimensionally. The lower interconnection structure includes a lower contact, a lower line on the lower contact, an upper contact on the lower line, and an upper line on the upper contact. The capacitor structure includes first electrode structures extending in a first direction and spaced apart from each other in a second direction intersecting the first direction, second electrode structures positioned alternately alongside the first electrode structures and spaced apart from each other in the second direction, and dielectric layers between the first electrode structures and the second electrode structures. Each of the first electrode structures and the second electrode structures includes a first lower electrode structure and a second lower electrode structure on a same level as a level of at least one of the lower contact and the lower line, and a first upper electrode structure and a second upper electrode structure on a same level as a level of at least one of the upper contact and the upper line.

According to various example embodiments, a substrate including a capacitor region and an interconnection region on both sides of the capacitor region, a capacitor structure including a first electrode structures extending in a first direction and spaced apart from each other in a second direction intersecting the first direction, second electrode structures positioned alternately alongside the first electrode structures and spaced apart from each other in the second direction, dielectric layers between the first electrode structures and the second electrode structures in the capacitor region, a lower contact, a lower line on the lower contact, an upper contact on the lower line, and an upper line on the upper contact in the interconnection region. Each of the first electrode structures and the second electrode structures includes a first lower electrode structure and a second lower electrode structure on a same level as a level of the lower contact or the lower line, and a first upper electrode structure and a second upper electrode structure on the upper contact or the upper line on a same level as a level of the upper line. The first upper electrode structure includes a first upper electrode line and a first upper barrier surrounding a sidewall of the first upper electrode line. The first lower electrode structure includes a first lower electrode line and a first lower barrier surrounding a sidewall of the first lower electrode line. At least one of the first upper barrier or the first lower barrier extends from a same level as a level of an upper surface of the upper line to a same level as a level of a lower surface of the upper contact, or extends from a same level as a level of an upper surface of the lower line to a same level as a level of a lower surface of the lower contact.

According to various example embodiments, a semiconductor storage device including a substrate, circuit devices on the substrate, a lower interconnection structure electrically connected to the circuit devices, and a capacitor structure, memory cells, and an input/output pad connected to the lower interconnection structure, and a controller electrically connected to the semiconductor storage device through the input/output pad and controlling the semiconductor storage device. The lower interconnection structure is in an interconnection region, and includes lower contacts on the circuit devices, lower lines on the lower contacts, upper contacts on the lower lines, and upper lines on the upper contacts. The capacitor structure includes first electrode structures extending in a first direction and spaced apart from each other in a second direction intersecting the first direction, second electrode structures positioned alternately alongside the first electrode structures and spaced apart from each other in the second direction, and dielectric layers between the first electrode structures and the second electrode structures. Each of the first electrode structures and the second electrode structures includes a first lower electrode structure and a second lower electrode structure on the same level as a level of at least one of the lower contact and the lower line, and a first upper electrode structure and a second upper electrode structure on the same level as a level of at least one of the upper contact and the upper line.

### BRIEF DESCRIPTION OF DRAWINGS

The above and other aspects, features, and advantages of various example embodiments will be more clearly understood from the following detailed description, taken in combination with the accompanying drawings, in which:

FIG. 1 is a cross-sectional view illustrating a semiconductor device according to some example embodiments;

FIG. 2 is a perspective view illustrating a capacitor structure and a lower interconnection structure of a semiconductor device according to some example embodiments;

FIG. 3 is a cross-sectional view taken along line I-I′ in FIG. 2;

FIG. 4 is an enlarged view illustrating a portion of a semiconductor device according to some example embodiments;

FIG. 5A is a cross-sectional view illustrating a region corresponding to FIG. 3;

FIG. 5B is an enlarged view illustrating a portion of a semiconductor device according to some example embodiments;

FIG. 6A is a cross-sectional view illustrating a region corresponding to FIG. 3;

FIG. 6B is an enlarged view illustrating a portion of a semiconductor device according to some example embodiments;

FIG. 7 is a cross-sectional view illustrating a region corresponding to FIG. 3;

FIG. 8 is a cross-sectional view illustrating a semiconductor device according to some example embodiments;

FIG. 9 is a cross-sectional view illustrating a semiconductor device according to some example embodiments;

FIGS. 10 to 15 are cross-sectional views illustrating a method of manufacturing a semiconductor device according to some example embodiments;

FIG. 16 is a view illustrating a data storage system including a semiconductor device according to some example embodiments;

FIG. 17 is a perspective view illustrating a data storage system including a semiconductor device according to some example embodiments; and

FIG. 18 is a cross-sectional view illustrating a semiconductor package according to some example embodiments.

### DETAILED DESCRIPTION

Hereinafter, embodiments of the present disclosure will be described as follows with reference to the accompanying drawings.

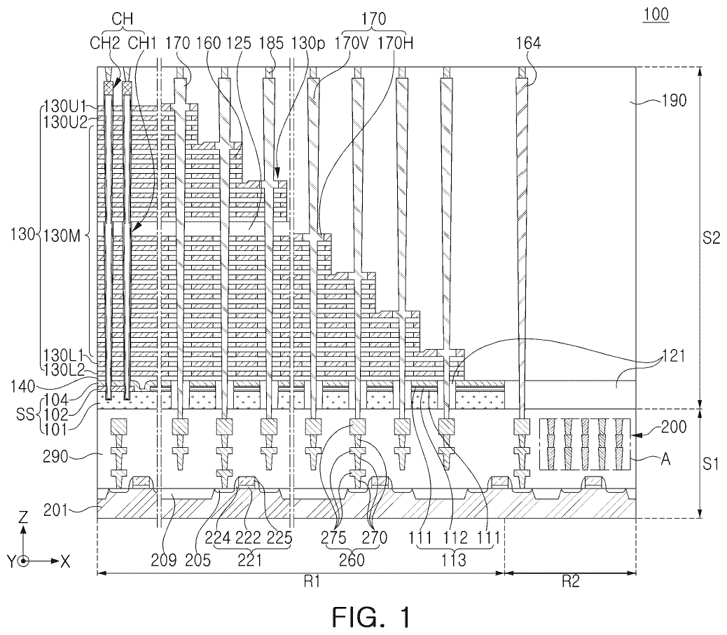

FIG. 1 is a cross-sectional view illustrating a semiconductor device according to some example embodiments.

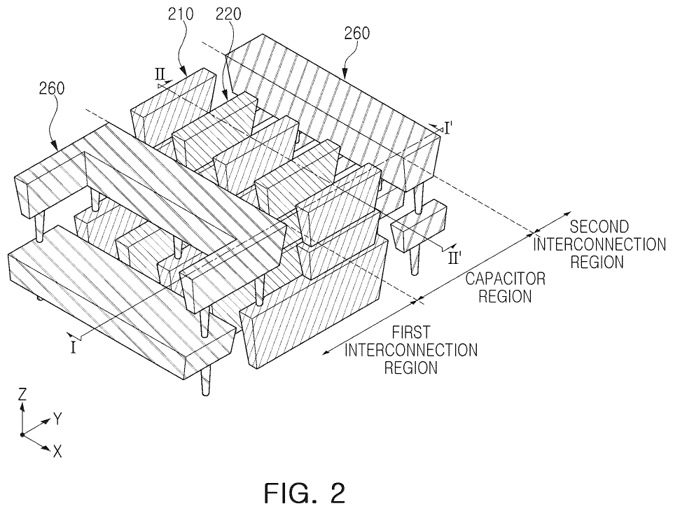

FIG. 2 is a perspective view illustrating a capacitor structure and a lower interconnection structure of a semiconductor device according to some example embodiments.

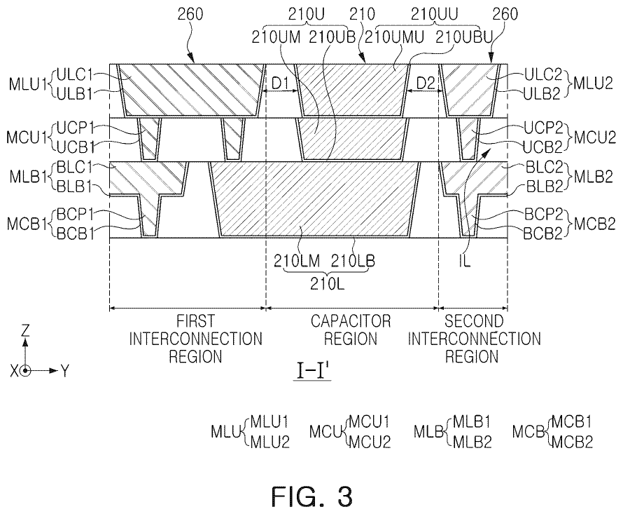

FIG. 3 is a cross-sectional view taken along line I-I′ in FIG. 2.

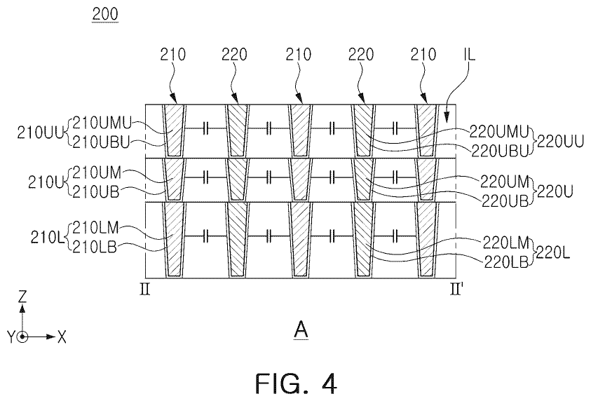

FIG. 4 is an enlarged view illustrating a portion of a semiconductor device and a cross-sectional view of a capacitor structure according to some example embodiments, taken along line II-II′ in FIG. 2.

Referring to FIGS. 1 to 4, the semiconductor device 100 may include a peripheral circuit structure PERI, which is a first semiconductor structure S1 including a substrate 201, and a memory cell structure CELL, which is a second semiconductor structure S2 including a plate layer 101. The memory cell structure CELL may be disposed on the peripheral circuit structure PERI. In some example embodiments, alternatively, the memory cell structure CELL may be disposed below the peripheral circuit structure PERI.

The second semiconductor structure S2 may include a first region R1 and a second region R2. In the first region R1, the memory cell array may be disposed. The second region R2 may correspond to a region for electrically connecting memory cells of the memory cell array to a peripheral circuit. The second region R2 may be disposed at least in one direction, for example, may be disposed on at least one end of the first region R1 in the X-direction.

The first semiconductor structure S1 may include a substrate 201, impurity regions 205 and device isolation regions 209 in the substrate 201, circuit devices 221 disposed on the substrate 201, a peripheral region insulating layer 290, circuit contact plugs 270, circuit interconnection lines 275, and a capacitor structure 200.

The substrate 201 may have an upper surface extending in the X-direction and the Y-direction. An active region may be defined in the substrate 201 by the device isolation regions 209. The impurity regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit devices 221 may include planar transistors. Each of the circuit devices 221 may include a circuit gate dielectric layer 222, a spacer layer 224, and a circuit gate electrode 225. The impurity regions 205 may be disposed as source/drain regions in the substrate 201 on both sides of the circuit gate electrode 225.

The peripheral region insulating layer 290 may be disposed on the circuit device 221 on the substrate 201. The peripheral region insulating layer 290 may include a plurality of insulating layers formed in different processes. The peripheral region insulating layer 290 may be formed of an insulating material.

The circuit contact plugs 270 and the circuit interconnection lines 275 may form a lower interconnection structure 260 electrically connected to the circuit devices 221 and the impurity regions 205. The circuit contact plugs 270 may have a cylindrical shape, and the circuit interconnection lines 275 may have a line shape. An electrical signal may be applied to the circuit device 221 through the circuit contact plugs 270 and the circuit interconnection lines 275. In a region not illustrated, the circuit contact plugs 270 may also be connected to the circuit gate electrode 225. The circuit interconnection lines 275 may be connected to the circuit contact plugs 270, may have a line shape, and may be disposed in a plurality of layers. The circuit contact plugs 270 and the circuit interconnection lines 275 may include a conductive material, for example, tungsten (W), copper (Cu), aluminum (Al), or the like, and each component may further include a diffusion barrier. However, example embodiments are not limited thereto. In example embodiments, the number of layers of the circuit contact plugs 270 and the circuit interconnection lines 275 may be varied.

According to various example embodiments, the lower interconnection structure 260 may be disposed in the interconnection region, and may include lower contacts MCB on the circuit devices 221, lower lines MLB on the lower contacts MCB, upper contacts MCU on the lower lines MLB, and upper lines MLU on the upper contacts MCU.

The upper lines MLU may include an upper conductive layer ULC and an upper contact barrier ULB disposed along a side surface and a lower surface of the upper conductive layer ULC. The upper contacts MCU may include an upper contact plug UCP and an upper contact barrier UCB disposed along a side surface and a lower surface of the upper contact plug UCP.

The lower lines MLB may include a lower conductive layer BLC and a lower line barrier BLB disposed along a side surface and a lower surface of the lower conductive layer BLC. The lower contacts MCB may include a lower contact plug BCP and a lower contact barrier BCB disposed along the side surface and the lower surface of the lower contact plug BCP.

According to various example embodiments, the lower conductive layer BLC may be integrated with and in direct contact with the lower contact plug BCP, and the lower line barrier BLB may be integrated with the lower contact barrier BCB. The upper contact barrier ULB may surround a sidewall and a lower surface of the upper conductive layer ULC and may cover an upper surface of the upper contact plug UCP. The upper conductive layer ULC may be spaced apart from the upper contact plug UCP by the upper contact barrier ULB.

The upper conductive layer ULC, the lower conductive layer BLC, the upper contact plug UCP, and the lower contact plug BCP may include a metal material such as aluminum (Al), tungsten (W), or molybdenum (Mo). The upper contact barrier ULB, the lower line barrier BLB, and the upper contact barrier UCB, the lower contact barrier BCB may include a metal nitride, for example, titanium nitride (TiN), tantalum nitride (TaN), or tungsten nitride (WN). However, example embodiments are not limited thereto.

The capacitor structure 200 may be disposed in a region overlapping horizontally the lower interconnection structure 260. In some example embodiments, the capacitor structure 200 may be disposed below the first region R1 of the first semiconductor structure S1 to the second semiconductor structure S2. The capacitor structure 200 may include lines and contacts disposed on the same level as a level of the other circuit contact plugs 270 and the circuit interconnection lines 275, respectively. The capacitor structure 200 may be horizontally spaced apart from other regions of the lower interconnection structure 260. The capacitor structure 200 may be electrically connected to a portion of the circuit devices 221. The capacitor structure 200 may be disposed in the second region R2, but example embodiments thereof is not limited thereto. In some example embodiments, the capacitor structure 200 may be disposed below the first region R1 of the second semiconductor structure S2, or may be disposed below both the first and second regions R1 and R2.

The capacitor structure 200 may include a first electrode structure 210 extending in the Y-direction and spaced apart from each other in the X-direction intersecting the Y-direction, second electrode structures 220 spaced apart from the first electrode structures 210 in the X-direction and alternately disposed, and dielectric layers IL disposed between the first electrode structures 210 and the second electrode structures 220. According to an example embodiment, each of the first electrode structures 210 and the second electrode structures 220 may include first lower electrode structures 210L and second lower electrode structures 220L disposed on the same level as a level of the lower contacts MCB or the lower lines MLB, and first upper electrode structures 210U and second upper electrode structures 220U disposed on the same level as a level of the upper contacts MCU or the upper lines MLU. The first electrode structures 210 may be disposed on the first upper electrode structures 210U and may further include first uppermost electrode structures 210UU disposed on the same level as a level of the upper lines MLU, and the second electrode structures 220 may be disposed on the second upper electrode structures 220U, and may further include second uppermost electrode structures 220UU disposed on the same level as a level of the upper lines MLU.

The first uppermost electrode structure 210UU may include a first uppermost electrode line 210UMU and a first uppermost electrode barrier 210UBU surrounding a sidewall of the first uppermost electrode line 210UMU. The first upper electrode structures 210U may include a first upper electrode line 210UM and a first upper electrode barrier 210UB surrounding a sidewall of the first upper electrode line 210UM. The first lower electrode structures 210L may include a first lower electrode line 210LM and a first lower electrode barrier 210LB surrounding a sidewall of the first lower electrode line 210LM.

The second uppermost electrode structure 220UU may include a second uppermost electrode line 220UMU and a second uppermost electrode barrier 220UBU surrounding a sidewall of the second uppermost electrode line 220UMU. The second upper electrode structures 220U may include a second upper electrode line 220UM and a second upper electrode barrier 220UB surrounding a sidewall of the second upper electrode line 220UM. The second lower electrode structures 220L may include a second lower electrode line 220LM and a second lower electrode barrier 220LB surrounding a sidewall of the second lower electrode line 220LM.

According to various example embodiments, the first lower electrode structures 210L may extend from the same level as a level of an upper surface of the lower lines MLB to the same level as a level of a lower surface of the lower contacts MCB.

According to an example embodiment, the first lower electrode barrier 210LB may extend from the same level as a level of an upper surface of the lower lines MLB to the same level as a level of a lower surface of the lower contacts MCB. The second lower electrode barrier 220LB may extend from the same level as a level of the upper surface of the lower lines MLB to the same level as a level of the lower surface of the lower contacts MCB.

The capacitor structure 200 may be disposed in the capacitor region, and the interconnection region may include a first interconnection region and a second interconnection region disposed on both sides of the capacitor region.

The lower interconnection structure 260 may include a first lower interconnection structure 260A disposed in the first interconnection region and a second lower interconnection structure 260B disposed in the second interconnection region. The first lower interconnection structure 260A may apply a first potential to the first electrode structure 210, and the second lower interconnection structure 260B may apply a second potential to the second electrode structure 220. The first interconnection region may include first upper lines MLU1 having a first potential among the upper lines MLU, and the second interconnection region may include second upper lines MLU2 having a second potential different from the first potential among the upper lines MLU.

According to various example embodiments, first upper electrode structures 210U may be electrically connected to the first upper lines MLU1 through the first lower electrode structures 210L and the upper contacts MCU. For example, the first electrode structures 210 may receive an electrical signal through the first upper lines MLU1. Specifically, the first upper contacts MCU1 may apply a bias to the first lower electrode structure 210L.

According to various example embodiments, the second upper electrode structures 220U may be electrically connected to the second upper lines MLU2 through the second lower electrode structures 220L and the upper contacts MCU. For example, the second electrode structures 220 may receive an electrical signal through the second upper lines MLU2. Specifically, the second upper contacts MCU2 may apply bias to the second lower electrode structure 220L.

Since the first electrode structure 210 receives the first potential, and the second electrode structure 220 receives the second potential, a potential difference may be formed between the first electrode structure 210 and the second electrode structure 220.

The amount of charge stored by the capacitor structure 200 may be proportional to a product of the potential difference and electric capacity of the capacitor structure 200. The electric capacity may be proportional to a product of a dielectric constant of the dielectric layers IL and an area in which the first electrode structure 210 and the second electrode structure 220, disposed on the left and right of the dielectric layers IL, oppose each other, and may be inversely proportional to a distance between the first electrode structure 210 and the second electrode structure 220 disposed on the left and right of the dielectric layers IL. In various example embodiments, by using a dual-damascene process, the process costs may be reduced, and by increasing the area in which the first electrode structure 210 and the second electrode structure 220 oppose each other, capacitance of the capacitor structure 200 may increase.

In various example embodiments, the number of layers included in the first upper electrode structures 210U and the second upper electrode structures 220U may be varied. The first uppermost electrode line 210UMU, the first upper electrode line 210UM, and the first lower electrode line 210LM may include a metal material, for example, tungsten (W), copper (Cu), or aluminum (Al). However, example embodiments are not limited thereto. The first uppermost electrode line 210UMU, the first upper electrode line 210UM, and the first lower electrode line 210LM may include the same material, but example embodiments are not limited thereto. The dielectric layers IL may be configured as insulating layers including an insulating material, for example, silicon oxide, silicon nitride, silicon carbide, or silicon oxynitride. However, example embodiments are not limited thereto. According to an example embodiment, the dielectric layers IL may include a plurality of insulating layers.

The first upper lines MLU1 may be spaced apart from the first uppermost electrode structure 210UU by a first distance D1 in the first direction, and the second upper lines MLU2 may be spaced apart from the first uppermost electrode structure 210UU by a second distance D2 in the first direction. According to various example embodiments, the first distance D1 and the second distance D2 may be the same. At least one of the first distance D1 or the second distance D2 may be about 2.5 μm or more. For example, at least one of the first distance D1 or the second distance D2 may be about 2.0 μm or more. When the distances are smaller than the above-mentioned numerical range, there may be limitations in performing the dual-damascene process.

A width of the first upper electrode structure 210U in the first direction (e.g., X-direction) and a width of the first upper electrode structure 210U in the second direction (e.g., Y-direction) may decrease toward an upper surface of the first lower electrode structure 210L.

The memory cell structure CELL, that is, the second semiconductor structure S2, may have the first and second regions R1 and R2, and may include a source structure SS, gate electrodes 130 stacked on the source structure SS, interlayer insulating layers 140 alternately stacked with the gate electrodes 130, channel structures CH disposed to penetrate through the stack structure of gate electrodes 130, and gate contact plugs 170 connected to the gate electrodes 130 and extending vertically. The memory cell structure CELL may include horizontal insulating layer 113 disposed below the gate electrodes 130, substrate insulating layers 121 disposed to penetrate through the plate layer 101, studs 185 on the gate contact plugs 170, and a cell region insulating layer 190 covering the gate electrodes 130.

In the memory cell structure CELL, in the first region R1, the gate electrodes 130 may be vertically stacked and may form memory cells or may be connected to the gate contact plugs 170. The second region R2 may be an external side region of the plate layer 101.

The source structure SS may include a plate layer 101, a first horizontal conductive layer 102, and a second horizontal conductive layer 104 stacked in order. The plate layer 101 may have a plate shape and may function as at least a portion of the common source line of the semiconductor device 100. The plate layer 101 may include a conductive material, for example, a semiconductor material. The plate layer 101 may further include impurities. The plate layer 101 may be provided as a polycrystalline semiconductor layer such as a polycrystalline silicon layer or an epitaxial layer.

The first and second horizontal conductive layers 102 and 104 may be stacked in order on an upper surface of the plate layer 101 in the region in which the channel structures CH are disposed. The first horizontal conductive layer 102 may function as a portion of the common source line of the semiconductor device 100, for example, the first horizontal conductive layer 102 together with the plate layer 101 may function as a common source line. The first horizontal conductive layer 102 may be directly connected to the channel layer in the channel structure CH. The first and second horizontal conductive layers 102 and 104 may include a semiconductor material, for example, polycrystalline silicon.

The horizontal insulating layer 113 may be disposed on the plate layer 101 on the same level as a level of the first horizontal conductive layer 102. The horizontal insulating layer 113 may include first and second horizontal insulating layers 111 and 112 alternately stacked on the plate layer 101. The horizontal insulating layer 113 may be layers remaining after a portion thereof is replaced with the first horizontal conductive layer 102 in the process of manufacturing the semiconductor device 100. The horizontal insulating layer 113 may include silicon oxide, silicon nitride, silicon carbide, or silicon oxynitride. However, example embodiments are not limited thereto. The first horizontal insulating layers 111 and the second horizontal insulating layer 112 may include different insulating materials.

The substrate insulating layers 121 may be disposed to penetrate through the plate layer 101, the horizontal insulating layer 113, and the second horizontal conductive layer 104. The substrate insulating layer 121 may include an insulating material, for example, silicon oxide, silicon nitride, silicon carbide, or silicon oxynitride. However, example embodiments are not limited thereto.

The gate electrodes 130 may be vertically stacked and spaced apart from the plate layer 101 and may form a stack structure together with the interlayer insulating layers 140. The stack structure may include vertically stacked lower and upper stack structures. The gate electrodes 130 may include first upper gate electrodes 130U1 and 130U2 forming string selection transistors, memory gate electrodes 130M forming a plurality of memory cells, and second lower gate electrodes 130L1 and 130L2 forming ground selection transistors. The number of memory gate electrodes 130M included in the memory cells may be determined depending on capacity of the semiconductor device 100.

The gate electrodes 130 may be stacked vertically spaced apart from each other on the first region R1 and may extend to different lengths in the X-direction forming step structures in the form of a staircase. Due to the step structure, the lower gate electrode 130 may extend longer than the upper gate electrode 130, and each of the gate electrodes 130 may have contact regions 130P exposed upwardly from the interlayer insulating layers 140. The gate electrodes 130 may be connected to the gate contact plugs 170 in the contact regions 130P, which are the end regions, respectively.

The gate electrodes 130 may include a metal material, for example, tungsten (W). In example embodiments, the gate electrodes 130 may include polycrystalline silicon or metal silicide material. The gate electrodes 130 may include the same material. In example embodiments, the gate electrodes 130 may further include a diffusion barrier. For example, the diffusion barrier may include tungsten nitride (WN), tantalum nitride (TaN), titanium nitride (TiN), or a combination thereof. However, example embodiments are not limited thereto.

The interlayer insulating layers 140 may be disposed between the gate electrodes 130. Similarly to the gate electrodes 130, the interlayer insulating layers 140 may be spaced apart from each other in a direction perpendicular to an upper surface of the plate layer 101 and may extend in the X-direction. The interlayer insulating layers 140 may include an insulating material such as silicon oxide or silicon nitride.

The channel structures CH may penetrate through the gate electrodes 130, may extend in the Z-direction and may be connected to the plate layer 101. Each of the channel structures CH may form a memory cell string and may be spaced apart from each other while forming rows and columns on the plate layer 101. The channel structures CH may be disposed to form a grid pattern on the X-Y plane or may be disposed in a zigzag shape in one direction. The channel structures CH may have a pillar shape and may have an inclined side surface having a width decreasing toward the plate layer 101.

The channel structures CH may include vertically stacked lower and upper channel structures CH1 and CH2. The channel structures CH may have a form in which the lower channel structures CH1 and the upper channel structures CH2 are connected to each other and may have a bent portion due to a difference in width in the connection region. However, in example embodiments, the number of channel structures stacked in the Z-direction may be varied. Each of the channel structures CH may include a channel layer disposed in the channel hole, a gate dielectric layer, a channel filling insulating layer, and a channel pad on an upper end.

The gate contact plugs 170 may be connected to the contact regions 130P of the gate electrodes 130. The gate contact plugs 170 may penetrate through at least a portion of the cell region insulating layer 190 and may be connected to each of the contact regions 130P of the gate electrodes 130 exposed upwardly. The gate contact plugs 170 may penetrate through the gate electrodes 130 below the contact regions 130P, the second horizontal conductive layer 104, the horizontal insulating layer 113, and the plate layer 101, and may be connected to the circuit interconnection lines 275 in the peripheral circuit structure PERI. The gate contact plugs 170 may be spaced apart from the gate electrodes 130 below the contact regions 130P by the contact insulating layers 160. The gate contact plugs 170 may be spaced apart from the plate layer 101, the horizontal insulating layer 113, and the second horizontal conductive layer 104 by the substrate insulating layers 121.

Each of the gate contact plugs 170 may have a horizontally expanded form in the contact region 130P. The gate contact plug 170 may include a vertical extension portion 170V extending in the Z-direction and a horizontal extension portion 170H extending horizontally from the vertical extension portion 170V and in contact with the gate electrode 130. The horizontal extension portion 170H may be disposed along a perimeter of the vertical extension portion 170V, and the entire side surface may be surrounded by the gate electrode 130. The gate contact plugs 170 may be spaced apart from the gate electrodes 130 below the contact regions 130P, that is, the gate electrodes 130 not electrically connected, by the contact insulating layers 160.

The gate contact plugs 170 may include at least one of a conductive material, for example, tungsten (W), copper (Cu), aluminum (Al), and alloys thereof. However, example embodiments are not limited thereto. In some example embodiments, the gate contact plugs 170 may include a barrier layer extending along a side surface and a bottom surface, or may have an air gap therein.

The contact insulating layers 160 may be disposed to surround a side surface of each of the gate contact plugs 170 below the contact regions 130P. The contact insulating layers 160 may be spaced apart from each other in the Z-direction around each of the gate contact plugs 170. The contact insulating layers 160 may be disposed on substantially the same level as a level of the gate electrodes 130, respectively. The contact insulating layers 160 may include an insulating material, for example, silicon oxide, silicon nitride, or silicon oxynitride. However, example embodiments are not limited thereto.

The studs 185 may form a cell interconnection structure electrically connected to memory cells in the memory cell structure CELL. The studs 185 may be connected to the channel structures CH and the gate contact plugs 170 and may be electrically connected to the channel structures CH and the gate electrodes 130. The studs 185 may include a metal, for example, tungsten (W), copper (Cu), aluminum (Al), or the like. However, example embodiments are not limited thereto.

The cell region insulating layer 190 may be disposed to cover the stack structure of the gate electrodes 130 and the gate contact plugs 170. The cell region insulating layer 190 may be formed of an insulating material and may include a plurality of insulating layers.

The through-plug 164 may be disposed in the second region R2 of the first semiconductor structure S1, which is an external side region of the plate layer 101 and may extend to the second semiconductor structure S2 through the cell region insulating layer 190. The through-plug 164 may be disposed to connect the studs 185 of the first semiconductor structure S1 to the circuit interconnection lines 275 of the second semiconductor structure S2. The through-plug 164 may include a conductive material, for example, a metal material such as tungsten (W), copper (Cu), or aluminum (Al). The through-plug 164 may be formed in the same process as the process of forming the gate contact plugs 170, may include the same material, and may have the same internal structure.

In the description below, the descriptions overlapping the above-described descriptions will not be provided.

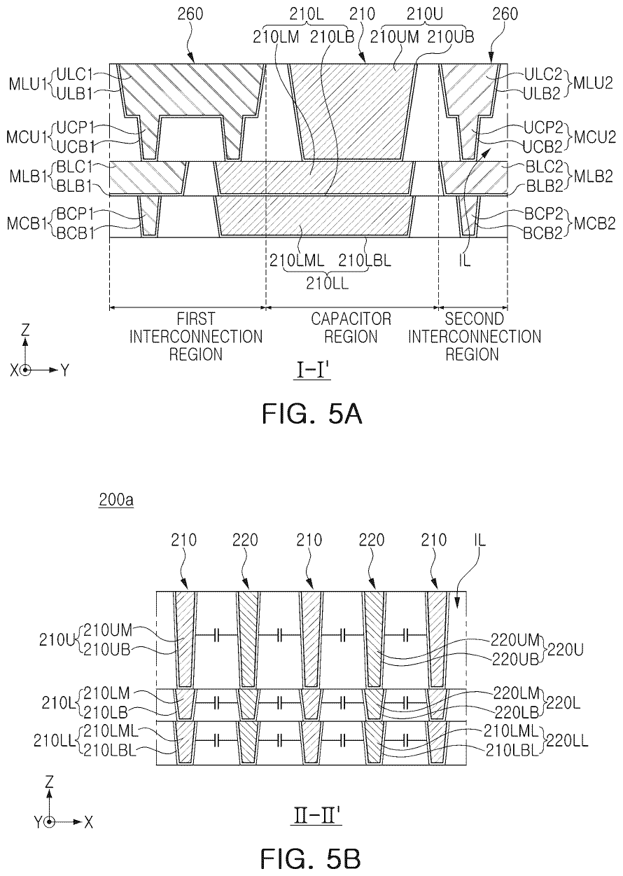

FIG. 5A is a cross-sectional view illustrating a region corresponding to FIG. 3.

FIG. 5B is an enlarged view illustrating a portion of a semiconductor device according to some example embodiments.

Referring to FIGS. 5A and 5B, in a capacitor structure 200A, first upper electrode structures 210U, second upper electrode structures 220U, upper contacts MCU and upper lines MLU may be formed by a dual-damascene process. The first lower electrode structures 210L, first lowermost electrode structures 210LL, lower contacts MCB and lower lines MLB may be formed by a single-damascene process. The first upper electrode structures 210U and the second upper electrode structures 220U may be spaced apart from the upper lines MLU in the first direction.

The first electrode structures 210 may be disposed below the first lower electrode structures 210L and may include the first lowermost electrode structures 210LL disposed on the same level as a level of the lower contacts MCB. The second electrode structures 220 may be disposed below the second lower electrode structures 220L and may include second lowermost electrode structures 220LL disposed on the same level as a level of the lower contacts MCB. The first upper electrode structures 210U may extend from the same level as a level of an upper surface of the upper lines MLU to the same level as a level of a lower surface of the upper contacts MCU.

The first lowermost electrode structures 210LL may include a first lowermost electrode line 210LML and a first lowermost electrode barrier 210LBL surrounding a sidewall and a lower surface of the first lowermost electrode line 210LML. According to some example embodiments, the first lower electrode barrier 210LB may surround a sidewall and a lower surface of the first lower electrode line 210LM, and the first lower electrode barrier 210LB may cover the upper surface of the first lowermost electrode line 210LML. The first lower electrode line 210LM may be spaced apart from the first lowermost electrode line 210LML by the first lower electrode barrier 210LB.

The second lowermost electrode structures 220LL may include a second lowermost electrode line 220LML and a second lowermost electrode barrier 220LBL surrounding a sidewall and a lower surface of the second lowermost electrode line 220LML. According to an example embodiment, the second lower electrode barrier 220LB may surround a sidewall and a lower surface of the second lower electrode line 220LM, and the second lower electrode barrier 220LB may cover an upper surface of the second lowermost electrode line 220LML. The second lower electrode line 220LM may be spaced apart from the second lowermost electrode line 220LML by the second lower electrode barrier 220LB.

The first lowermost electrode line 210LML and the second lowermost electrode line 220LML may include a metal material such as aluminum (Al), tungsten (W), or molybdenum (Mo). The first lowermost electrode barrier 210LBL and the second lowermost electrode barrier 220LBL may include a metal nitride, such as titanium nitride (TiN), tantalum nitride (TaN), or tungsten nitride (WN). However, example embodiments are not limited thereto.

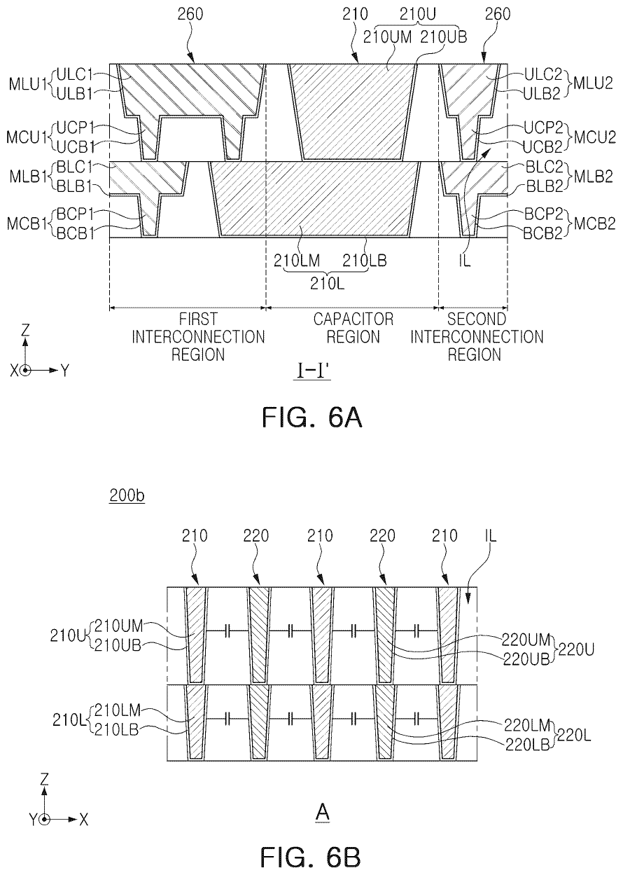

FIG. 6A is a cross-sectional view illustrating a region corresponding to FIG. 3.

FIG. 6B is an enlarged view illustrating a portion of a semiconductor device according to some example embodiments.

Referring to FIGS. 6A and 6B, the capacitor structure 200B and the lower interconnection structure 260 may be formed by a dual-damascene process. According to some example embodiments, lower contacts MCB and lower lines MLB may be formed by a dual-damascene process, and upper contacts MCU and upper lines MLU may be formed by a dual-damascene process. For example, the first lower electrode structures 210L may extend from the same level as a level of an upper surface of the lower lines MLB to the same level as a level of a lower surface of the lower contacts MCB, and the first upper electrode structures 210U may extend from the same level as a level of an upper surface of the upper lines MLU to the same level as a level of a lower surface of the upper contacts MCU.

By the dual-damascene process, the lower conductive layer BLC may be integrated with and in direct contact with the lower contact plug BCP, and the lower line barrier BLB may be integrated with the lower contact barrier BCB. Also, the upper conductive layer ULC may be integrated with and in direct contact with the upper contact plug UCP, and the upper contact barrier ULB may be integrated with the upper contact barrier UCB.

According to various example embodiments, the first upper electrode barrier 210UB may extend from the same level as a level of an upper surface of the upper lines MLU to the same level as a level of a lower surface of the upper contacts MCU, and the first lower electrode barrier 210LB may extend from the same level as a level of an upper surface of the lower lines MLB to the same level as a level of a lower surface of the lower contacts MCB. The first upper electrode structures 210U and the second upper electrode structures 220U may be spaced apart from the upper lines MLU in the first direction.

Using the above process, process costs may be reduced and capacitor capacity may be increased, such that a semiconductor device having improved electrical properties may be provided.

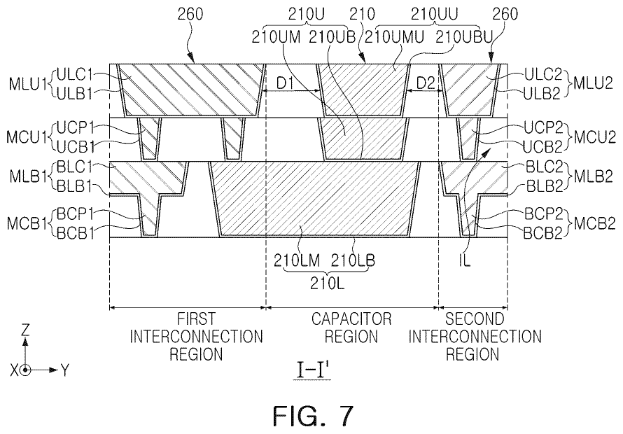

In FIG. 7, the first upper lines MLU1 may be spaced apart from the first uppermost electrode structure 210UU by the first distance D1 in the Y-direction, and the second upper lines MLU2 may be spaced apart from the first uppermost electrode structure 210UU by the second distance D2 in the Y-direction, so the distance in the Y-direction between the first and second upper lines MLU1, MLU2 and the first uppermost electrode structure 210UU may be different. According to various example embodiments, the first upper lines MLU1 may be spaced apart from the first uppermost electrode structure 210UU in the Y-direction by a first distance D1, and the second upper lines MLU2 may be spaced apart from the first uppermost electrode structure 210UU in the Y-direction by a second distance D2. The first distance D1 may be greater than the second distance D2, but example embodiments are not limited thereto. At least one of the first distance D1 or the second distance D2 may be about 2.5 um or more.

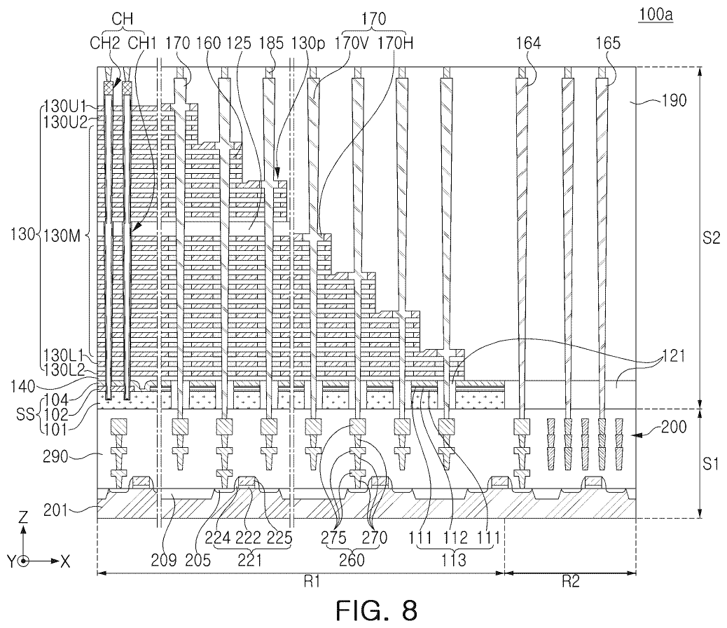

FIG. 8 is a cross-sectional view illustrating a semiconductor device according to some example embodiments.

Referring to FIG. 8, in a semiconductor device 100A, a second semiconductor structure S2, that is, the memory cell structure CELL, may further include capacitor contacts 165.

The capacitor contacts 165 may penetrate through the cell region insulating layer 190 and may be connected to the capacitor structure 200 of the first semiconductor structure S1. The capacitor contacts 165 may be connected to the second electrode structure (220, see FIG. 4) to apply a second potential. The capacitor contacts 165 may include a conductive material, for example, tungsten (W), copper (Cu), aluminum (Al), or the like. However, example embodiments are not limited thereto.

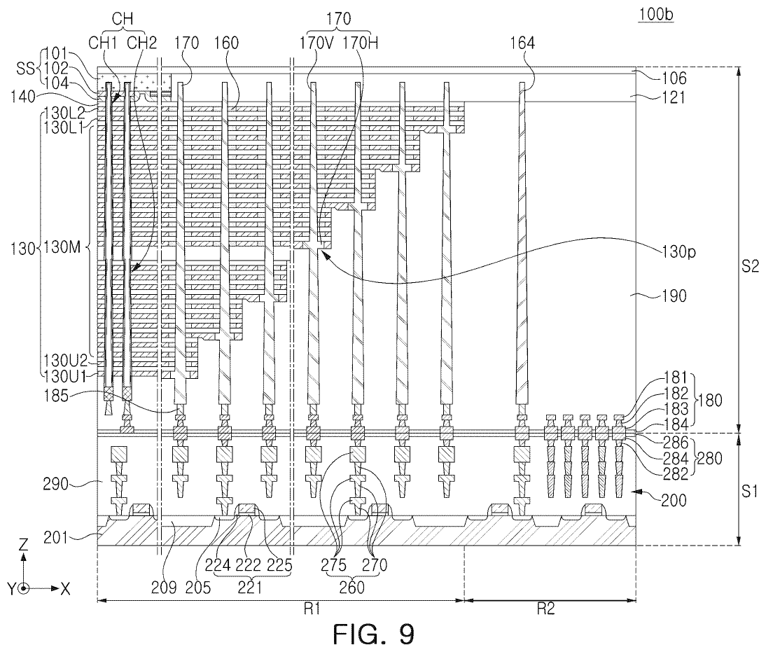

FIG. 9 is a cross-sectional view illustrating a semiconductor device according to an example embodiment.

Referring to FIG. 9, the semiconductor device 100B may include a first semiconductor structure S1 and a second semiconductor structure S2 bonded to each other using a wafer bonding method.

The description of the peripheral circuit structure PERI in FIG. 1 may be applied to the first semiconductor structure S1. However, the first semiconductor structure S1 may further include first bonding vias 282, first bonding pads 284, and first bonding insulating layer 286, which are the first bonding structure 280. The first bonding via 282 may be connected to a lower interconnection structure 260. The first bonding pad 284 may be connected to the first bonding via 282. The first bonding via 282 and the first bonding pad 284 may include a conductive material, for example, tungsten (W), copper (Cu), aluminum (Al), or the like, and each component may further include a diffusion barrier. The first bonding insulating layer 286 may also function as a diffusion barrier of the first bonding pad 284 and may include at least one of SiCN, SiO, SiN, SiOC, SiON and SiOCN. The first bonding insulating layer 286 may have a thickness smaller than that of the first bonding pad 284, but example embodiments are not limited thereto.

The first bonding pads 284 may be connected to the second bonding pads 184 of the second semiconductor structure S2. The first bonding structure 280 may be in direct contact with and bonded or connected to the second bonding structure 180 by hybrid bonding. For example, the first bonding pad 284 may be in contact with and bonded to the second bonding pad 184 by copper-to-copper bonding, and the first bonding insulating layer 286 may be in contact with and bonded to the second bonding insulating layer 186 by dielectric-to-dielectric bonding. The first bonding structure 280, together with the second bonding structure 180, may provide an electrical connection path according to the bonding between the first semiconductor structure S1 and the second semiconductor structure S2. A portion of the first bonding pads 284 may not be connected to the lower circuit interconnection lines 275 and may be disposed only for bonding. The first bonding insulating layer 286 may be disposed around the first bonding pads 284.

The description of the memory cell structure CELL in FIG. 1 may be applied to the second semiconductor structure S2. The second semiconductor structure S2 may further include second bonding vias 182, second bonding pads 184, and second bonding insulating layer 186, which are bonding structures. The second semiconductor structure S2 may further include cell interconnection lines 181, and a passivation layer 106 covering the upper surface of the plate layer 101.

The second bonding vias 182 and the second bonding pads 184 may be disposed below studs 185. In some example embodiments, cell interconnection lines 181 may be further disposed between the second bonding vias 182 and the studs 185. The second bonding vias 182 may connect the studs 185 to the second bonding pads 184, and the second bonding pads 184 may be bonded to the first bonding pads 284 of the first semiconductor structure S1. The second bonding insulating layer 186 may be bonded and connected to the first bonding insulating layer 286 of the first semiconductor structure S1. The second bonding vias 182 and the second bonding pads 184 may include a conductive material, for example, copper (Cu). The second bonding insulating layer 186 may include, for example, at least one of SiO, SiN, SiCN, SiOC, SiON, and SiOCN. However, example embodiments are not limited thereto.

The cell interconnection lines 181 may form an upper interconnection structure electrically connected to memory cells in the first semiconductor structure S1. The cell interconnection lines 181 may be connected to the gate contact plugs 170 and the through-plug 164, and may be electrically connected to the gate electrodes 130 and the channel structures CH. In example embodiments, the number of interconnection lines included in the upper interconnection structure may be varied. The cell interconnection lines 181 may include a metal, for example, tungsten (W), copper (Cu), aluminum (Al), or the like. However, example embodiments are not limited thereto.

The passivation layer 106 may be disposed on an upper surface of the plate layer 101 and may protect the semiconductor device 100B. The passivation layer 106 may include an insulating material, for example, the passivation layer 106 may include at least one of silicon oxide, silicon nitride, and silicon carbide, and in example embodiments, the passivation layer 106 may include a plurality of insulating layers. In the example embodiment, upper ends of the gate contact plugs 170 may be disposed in the substrate insulating layer 121. However, example embodiments are not limited thereto.

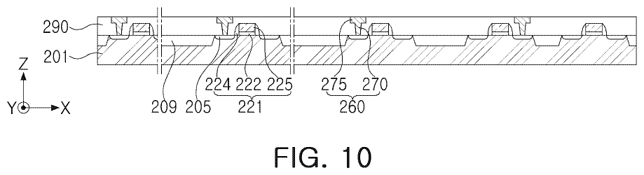

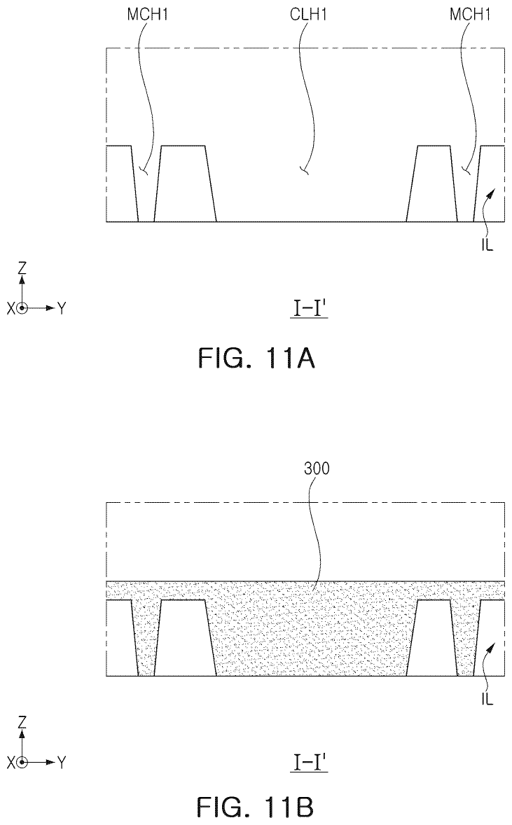

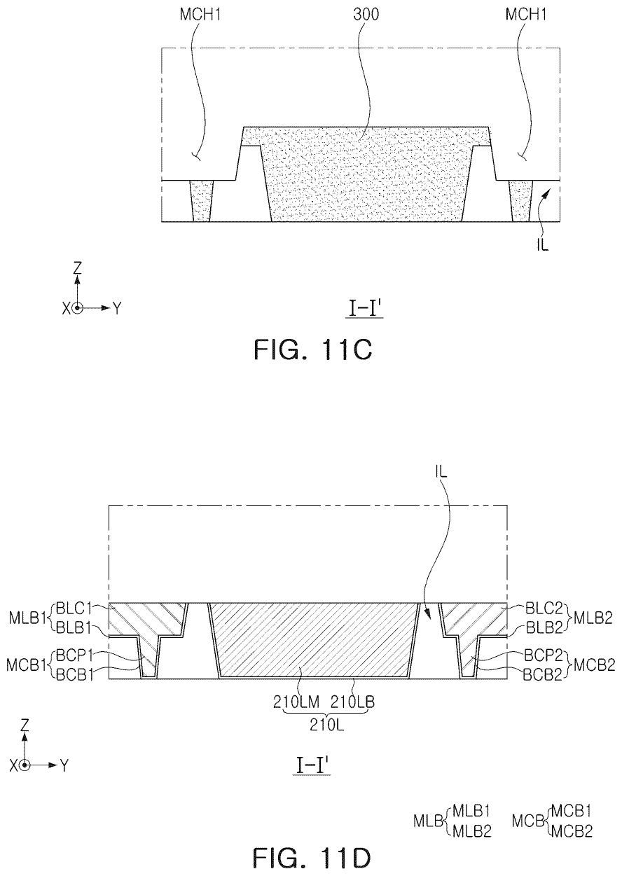

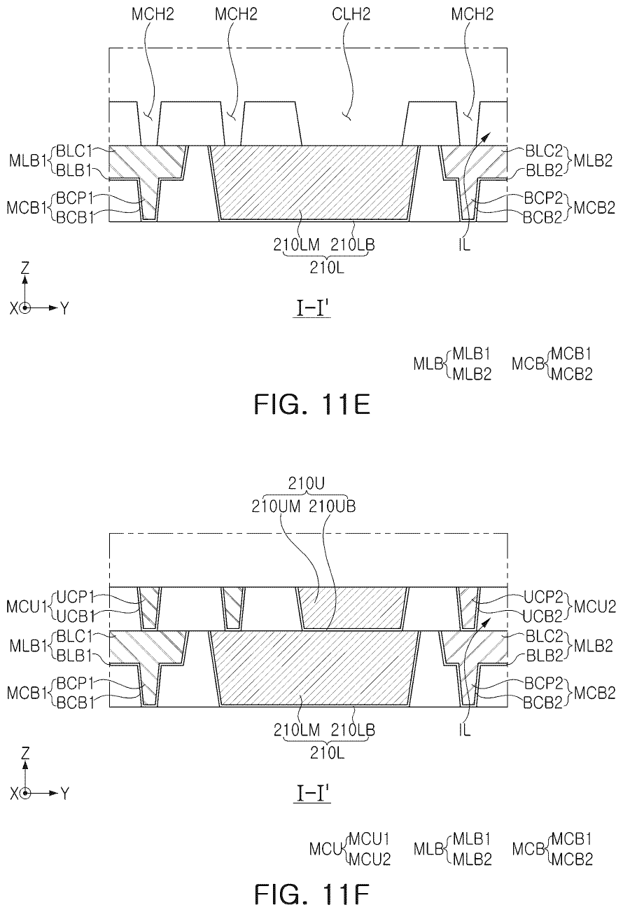

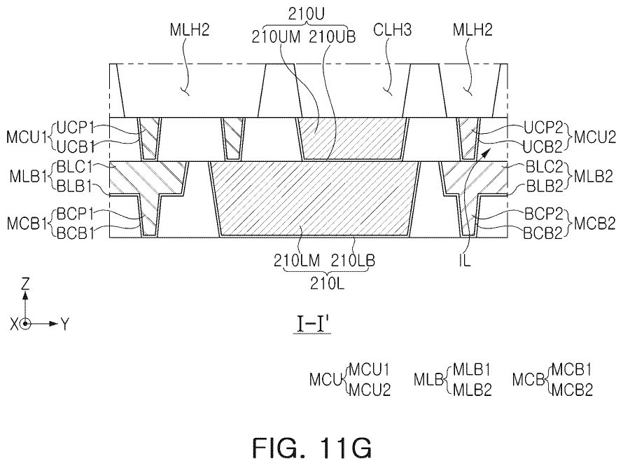

FIGS. 10 to 15 are cross-sectional views illustrating a method of manufacturing a semiconductor device according to an example embodiment. FIGS. 10, 12, 13, 14, and 15 illustrate regions corresponding to FIG. 1, and FIGS. 11A to 11G illustrate regions corresponding to FIG. 3.

Referring to FIG. 10, a portion of circuit devices 221 and lower interconnection structures 260 may be formed on a substrate 201.

First, device isolation regions 209 may be formed in the substrate 201, and circuit gate dielectric layer 222 and circuit gate electrode 225 may be formed in order on the substrate 201. The device isolation regions 209 may be formed, for example, by a shallow trench device isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of polycrystalline silicon or a metal silicide layer, but example embodiments are not limited thereto. Thereafter, a spacer layer 224 and impurity regions 205 may be formed on both sidewalls of the circuit gate dielectric layer 222 and the circuit gate electrode 225. In various example embodiments, the spacer layer 224 may include a plurality of layers, the impurity regions 205 may be formed by performing an ion implantation process.

Among the lower interconnection structures 260, the circuit contact plugs 270 may be formed by forming a portion of the peripheral region insulating layer 290, removing a portion by etching and filling a conductive material. Circuit interconnection lines 275 may be formed, for example, by depositing a conductive material and patterning the material, but an example embodiment thereof is not limited thereto. According to various example embodiments, the circuit contact plugs 270 and the circuit interconnection lines 275 may be formed by a dual-damascene process, but the process is not limited to the dual-damascene process.

The peripheral region insulating layer 290 may include a plurality of insulating layers. A portion of the peripheral region insulating layer 290 may be formed in each of processes of forming the lower interconnection structures 260.

Referring to FIG. 11A, a dielectric layer IL included in the peripheral region insulating layer 290 may be formed and may be patterned, thereby forming a first contact hole MCH1 and a first capacitor line hole CLH1. The distance between the external side of the first contact hole MCH1 and the external side of the first capacitor line hole CLH1 may be about 2.5 μm or more. According to an example embodiment, the distance between the external side of the first contact hole MCH1 and the external side of the first capacitor line hole CLH1 may be about 2 μm or more. When the distance is smaller than the above-mentioned numerical range, deviation of the upper surface of the mask layer 300 may occur in the process in FIG. 11B described later. Deviation of the upper surface of the mask layer 300 may be an obstacle in the dual damascene process.

Referring to FIG. 11B, the mask layer 300 may be formed to fill the first contact hole MCH1 and the first capacitor line hole CLH1.

The mask layer 300 may be formed of a silicon-including material such as silicon oxide, silicon oxynitride, silicon nitride, or polysilicon, a carbon-containing material made of hydrocarbon compounds or derivatives thereof, such as amorphous carbon layer (ACL), or spin-on hardmask (SOH), a bottom anti-reflective coating (BARC), a metal or organic material. For example, the mask layer 300 may be a spin-on hardmask layer. However, example embodiments are not limited thereto.

Referring to FIG. 11C, the first interconnection line hole MLH1 may be formed in the region corresponding to the lower lines (MLB, see FIG. 3).

The mask layer 300 and the dielectric layer IL may be etched through a photolithography process and an etching process.

Referring to FIG. 11D, the mask layer 300 may be removed, and lower contacts MCB, lower lines MLB, and a first lower electrode structure 210L may be formed.

A barrier material and a conductive material may be filled in the region from which the mask layer 300 is removed. Specifically, the first lower electrode line 210LM may be formed by filling a conductive material in the first lower electrode barrier 210LB and the first capacitor line hole CLH1 surrounding a sidewall and a lower surface of the first capacitor line hole (CLH1, see FIG. 11A).

Also, a lower contact barrier BCB and a lower line barrier BLB may be formed surrounding a sidewall and lower surface of the first contact hole (MCH1, see FIG. 11A) and the first interconnection line hole (MLH1, see FIG. 11c). A lower contact plug BCP and a lower conductive layer BLC may be formed by filling a conductive material in the first contact hole (MCH1, see FIG. 11A) and the first interconnection line hole (MLH1, see FIG. 11C). A planarization process may be performed if desired.

Referring to FIG. 11E, the dielectric layer IL may be formed and may be patterned, thereby forming a second contact hole MCH2 and a second capacitor line hole CLH2.

Referring to FIG. 11F, upper contacts MCU and a first upper electrode structure 210U may be formed in each of the second contact hole MCH2 and the second capacitor line hole CLH2.

An upper contact barrier UCB and a first upper electrode barrier 210UB surrounding a sidewall and a lower surface of each of the second contact hole MCH2 and the second capacitor line hole CLH2 may be formed. The upper contact barrier UCB and the first upper electrode barrier 210UB may cover an upper surface of the dielectric layer IL. Thereafter, the upper contact plug UCP and the first upper electrode line 210UM may be formed by filling a conductive material to in each of the second contact hole MCH2 and the second capacitor line hole CLH2. The upper contact plug UCP and the first upper electrode line 210UM may cover an upper surface of the dielectric layer IL. A material on an upper surface of the dielectric layer IL may be removed through a planarization process.

Referring to FIG. 11G, the dielectric layer IL may be formed and may be patterned, thereby forming a third contact hole MCH3 and a third capacitor line hole CLH3.

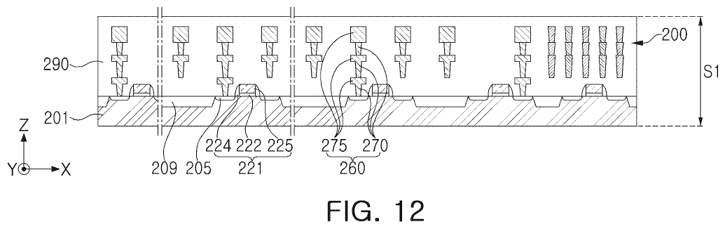

Referring to FIG. 12, upper lines MLU and first uppermost electrode structures 210UU may be formed by performing substantially the same process as in FIG. 11F. Accordingly, the capacitor structure 200 and the lower interconnection structure 260 may be formed. The peripheral region insulating layer 290 may be formed to cover the circuit devices 221 and the lower interconnection structures 260 by forming a portion thereof in an upper portion of the uppermost circuit interconnection line 275. Accordingly, the first semiconductor structure S1 may be formed.

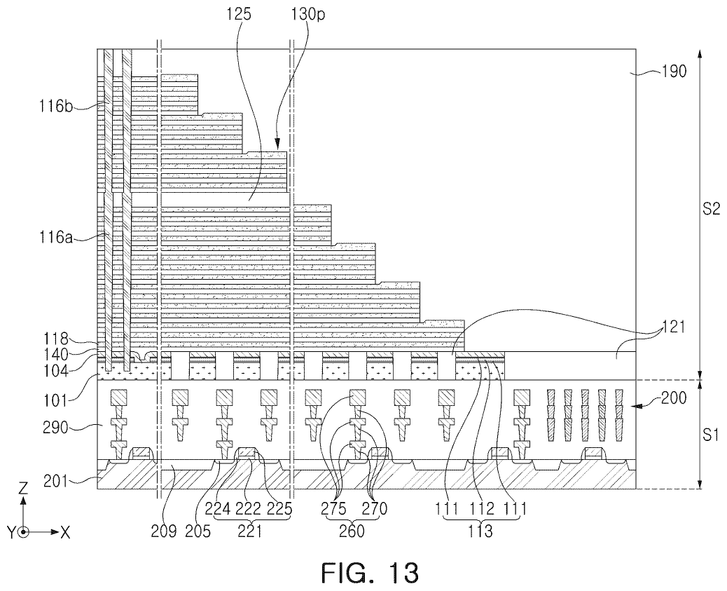

Referring to FIG. 13, a plate layer 101, a horizontal insulating layer 113, a second horizontal conductive layer 104, and a substrate insulating layer 121 may be formed on the first semiconductor structure S1. A preliminary stack structure may be formed by alternately stacking the sacrificial insulating layers 118 and the interlayer insulating layers 140, which form a lower stack structure, on the second horizontal conductive layer 104, and a step structure may be formed by etching the preliminary stack structure. The first sacrificial channel layers 116A penetrating the lower stack structure may be formed. The sacrificial insulating layers 118 and the interlayer insulating layers 140, which form the upper stack structure, may be alternately stacked on the lower stack structure, a step structure and a contact region 130P may be formed, and a second sacrificial channel layer 116B penetrating the upper stack structure may be formed.

The plate layer 101 may be formed on the peripheral region insulating layer 290. The plate layer 101 may be formed of, for example, polycrystalline silicon and may be formed through a CVD process. The polycrystalline silicon forming the plate layer 101 may include impurities.

The first and second horizontal insulating layers 111 and 112 included in the horizontal insulating layer 113 may be alternately stacked on the plate layer 101. A portion of the horizontal insulating layer 113 may be replaced with the first horizontal conductive layer 102 in FIG. 1 through a subsequent process. The first horizontal insulating layers 111 may include a material different from that of the second horizontal insulating layer 112. For example, the first horizontal insulating layers 111 may be formed of the same material as that of the interlayer insulating layers 140, and the second horizontal insulating layer 112 may be formed of the same material as that of the subsequent sacrificial insulating layers 118. A portion of regions of the horizontal insulating layer 113, for example, a portion of the second region R2 of the plate layer 101, may be removed by a patterning process.

The second horizontal conductive layer 104 may be formed on the horizontal insulating layer 113 and may be in contact with the plate layer 101 in the region in which the horizontal insulating layer 113 is removed. Accordingly, the second horizontal conductive layer 104 may be bent along ends of the horizontal insulating layer 113, may cover the ends and may extend to the plate layer 101.

The substrate insulating layer 121 may be formed in the regions in which the gate contact plugs 170 (see FIG. 1) of the first region R1 may be disposed and the second region R2. The substrate insulating layer 121 may be formed by removing a portion of the plate layer 101, the horizontal insulating layer 113, and the second horizontal conductive layer 104, and filling an insulating material. After filling the insulating material, a planarization process may be further performed using a chemical mechanical polishing (CMP) process. Accordingly, an upper surface of the substrate insulating layer 121 may be substantially coplanar with an upper surface of the second horizontal conductive layer 104.

First, a preliminary stack structure may be formed by alternately stacking the sacrificial insulating layers 118 and the interlayer insulating layers 140 on the second horizontal conductive layer 104. In this process, the sacrificial insulating layers 118 and the interlayer insulating layers 140 may be formed in a region on a level on which the first channel structures CH1 (see FIG. 1) are disposed. An upper interlayer insulating layer 125 having a relatively great thickness may be formed on an uppermost portion.

The sacrificial insulating layers 118 may be replaced with the gate electrodes 130 (see FIG. 1) through a subsequent process. The sacrificial insulating layers 118 may be formed of a material different from that of the interlayer insulating layers 140 and may be formed of a material etched with etch selectivity under specific etching conditions for the interlayer insulating layers 140. For example, the interlayer insulating layer 140 and the upper interlayer insulating layer 125 may be formed of at least one of silicon oxide, silicon oxynitride, or silicon nitride, and the sacrificial insulating layers 118 may be formed of a material different from that of the interlayer insulating layer 140, selected from among silicon, silicon oxide, silicon carbide, and silicon nitride. In various example embodiments, a thickness of the interlayer insulating layers 140 may be different. Also, thicknesses of the interlayer insulating layers 140 and the sacrificial insulating layers 118 and the number of films included therein may be varied from illustrated examples.

Thereafter, a photolithography process and an etching process for the sacrificial insulating layers 118 may be repeatedly performed using a mask layer such that the upper sacrificial insulating layers 118 may extend shorter than the lower sacrificial insulating layers 118 in the first region R1. Accordingly, the sacrificial insulating layers 118 may form a step structure in a staircase shape in predetermined unit, and the contact regions 130P disposed in the uppermost portion of the sacrificial insulating layers 118 may be exposed upwardly.

The first sacrificial channel layers 116A may be formed in the region corresponding to the first channel structures CH1 (see FIG. 1) in the first region R1. The first sacrificial channel layers 116A may be formed by forming lower channel holes to penetrate through the lower stack structure and depositing a material forming the first sacrificial channel layers 116A in the lower channel holes. The first sacrificial channel layers 116A may include, for example, polycrystalline silicon.

The second sacrificial channel layers 116B may be formed by forming upper channel holes to penetrate through the upper stack structure and to expose the upper end of the first sacrificial channel layers 116A and depositing a material forming the second sacrificial channel layers 116B in the upper channel holes in an upper portion of the first sacrificial channel layers 116A. The second sacrificial channel layers 116B may include, for example, polycrystalline silicon.

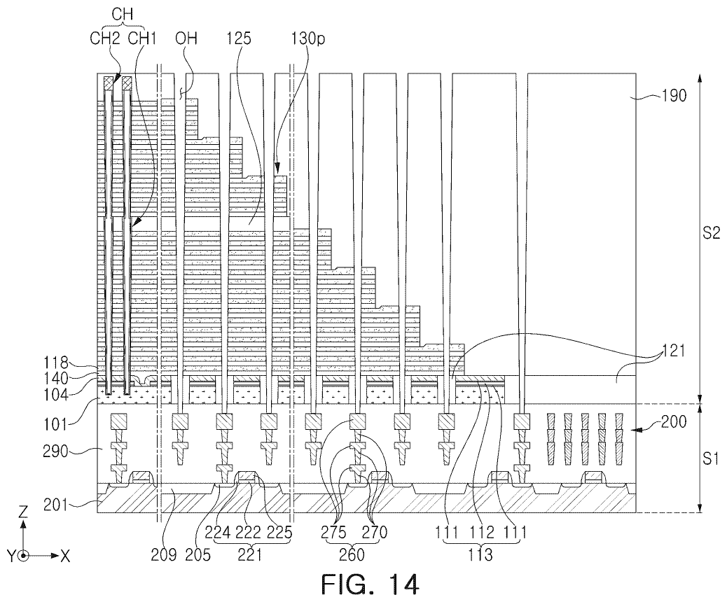

Referring to FIG. 14, the first and second sacrificial channel layers 116a and 116b may be removed, the channel structures CH may be formed, and openings OH may be formed.

The channel structures CH may be formed by forming channel holes by removing the first and second sacrificial channel layers 116a and 116b and filling the channel holes. Specifically, a cell region insulating layer 190 covering the stack structure may be formed, and a gate dielectric layer, a channel layer, a channel filling insulating layer, and a channel pad may be formed in order in the channel holes penetrating through the cell region insulating layer 190 and the stack structure, thereby forming the channel structures CH. The channel layer may be formed of a conductive material, for example, polycrystalline silicon.

In various example embodiments, in the stack structure, a lower step structure may be formed, a lower step structure and a portion of a cell region insulating layer 190 covering the lower step structure may be formed, an upper stack structure may be formed on the lower stack structure, and the upper step structure and the remaining cell region insulating layer 190 may be further formed. In this case, to form the channel structures CH, a lower channel hole penetrating the lower step structure and an upper channel hole penetrating the upper step structure may be formed separately. Accordingly, the channel structures CH may include the lower channel structure CH1 corresponding to the lower channel hole and the upper channel structure CH2 corresponding to the upper channel hole.

Thereafter, openings OH may be formed in the region in which the gate contact plugs 170 and in the through-plug 164 in FIG. 1 may be formed. Before the forming the openings OH, a portion of the cell region insulating layer 190 covering the channel structures CH may be further formed. The openings OH may have a cylindrical hole shape, may penetrate through the substrate insulating layer 121, and may extend to the first semiconductor structure S1.

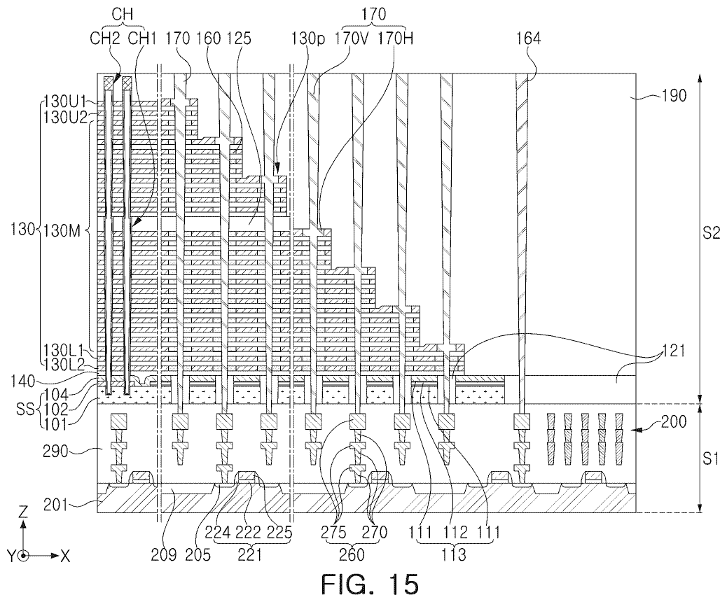

Referring to FIG. 15, a portion of the sacrificial insulating layers 118 exposed through the openings OH may be removed, contact insulating layers 160 may be formed, isolation openings may be formed, the sacrificial insulating layers 118 may be removed, and gate electrodes 130 may be formed. By depositing a conductive material in the openings OH, gate contact plugs 170 and through-plugs 164 may be formed.

First, the contact insulating layers 160 may be deposited, for example, by an ALD process. The contact insulating layers 160 may be formed on a side surface of the openings OH other than the contact region 130P. The contact insulating layers 160 may include an insulating material such as oxide or silicon oxide, for example.

Thereafter, isolation openings extending to the plate layer 101 may be formed through the sacrificial insulating layers 118 and the interlayer insulating layers 140. Through the isolation openings, the sacrificial insulating layers 118 may be selectively removed with respect to the interlayer insulating layers 140 and the contact insulating layers 160. The gate electrodes 30 may be formed by filling a conductive material in the region from which the sacrificial insulating layers 118 are removed. The conductive material may include metal, polycrystalline silicon, or metal silicide material.

Thereafter, gate contact plugs 170 and through-plugs 164 may be formed by depositing a conductive material in the openings OH. Since the gate contact plugs 170 and the through-plugs 164 are formed together in the same process, the gate contact plugs 170 and the through-plugs 164 may have the same structure. The gate contact plugs 170 may be formed to have a horizontal extension portion 170H (see FIG. 1) in the contact regions 130P and, accordingly, the gate contact plugs 170 may be physically and electrically connected to the gate electrodes 130.

Thereafter, referring to FIG. 1 together, by forming the studs 185 connected to upper ends of the gate contact plugs 170 and the through-plugs 164, the semiconductor device 100 may be manufactured.

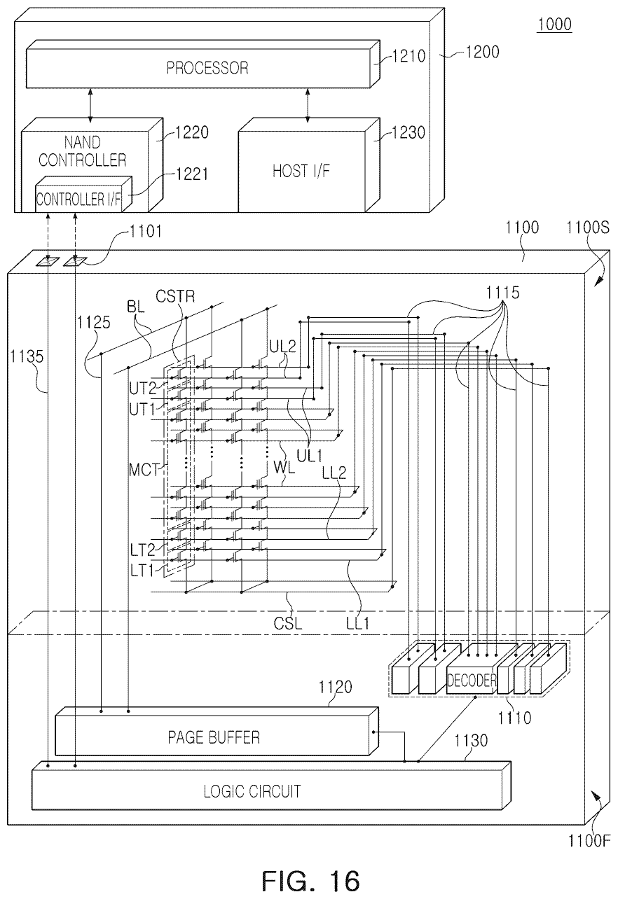

FIG. 16 is a view illustrating a data storage system including a semiconductor device according to various example embodiments.

Referring to FIG. 16, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiments with reference to FIGS. 1 to 9. The semiconductor device 1100 may include a first structure 1100F and a second structure 1100S on the first structure 1100F. In the example embodiments, the first structure 110OF may be disposed on the side of the second structure 1100S. The first structure 110OF may be implemented as a peripheral circuit structure including a decoder circuit 1110, a page buffer 1120, and a logic circuit 1130. The second structure 1100S may be implemented as a memory cell structure including a bitline BL, a common source line CSL, wordlines WL, first and second gate upper lines UL1 and UL2, first and second gate lower lines LL1 and LL2 and memory cell strings CSTR disposed between the bitline BL and the common source line CSL.

In the second structure 1100S, each of the memory cell strings CSTR may include lower transistors LT1 and LT2 adjacent to the common source line CSL, upper transistors UT1 and UT2 adjacent to the bitline BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in the example embodiments.

In various example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

In the example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a gate-induced drain leakage (GIDL) phenomenon.

The common source line CSL, the first and second gate lower lines LL1 and LL2, the wordlines WL, and the first and second gate upper lines UL1 and UL2 may be electrically connected to the decoder circuit 1110 through first connection interconnections 1115 extending from the first structure 1100F to the second structure 1100S. The bitlines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In the example embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

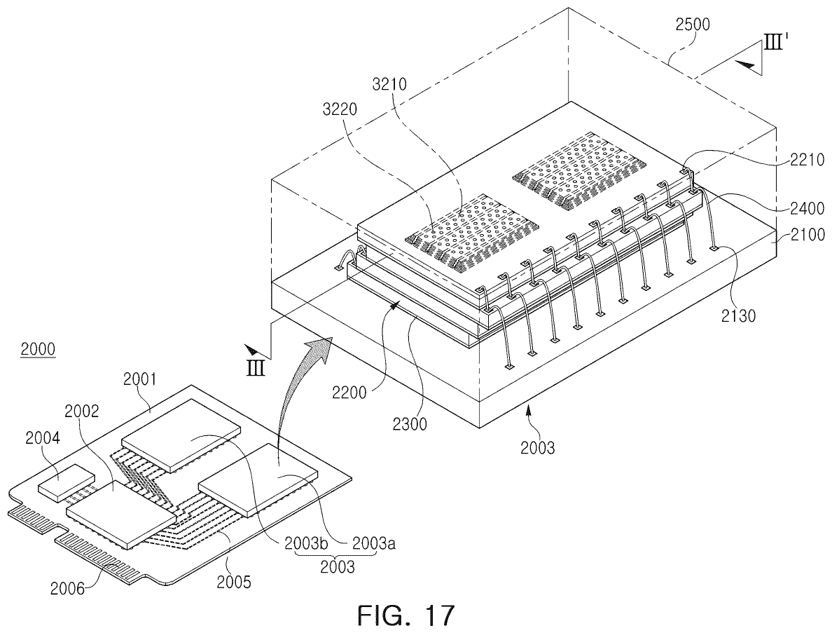

FIG. 17 is a perspective view illustrating a data storage system including a semiconductor device according to various example embodiments.

Referring to FIG. 17 a data storage system 2000 in some example embodiments may include a main board 2001, a controller 2002 mounted on the main board 2001, one or more semiconductor packages 2003, and a DRAM 2004. The semiconductor package 2003A and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may be varied depending on a communication interface between the data storage system 2000 and the external host. In the example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In some example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003A.

The controller 2002 may write data to or may read data from the semiconductor package 2003A, and may improve an operating speed of the data storage system 2000.

The DRAM 2004 may be configured as a buffer memory for alleviating a difference in speeds between the semiconductor package 2003A, which is a data storage space, and an external host. The DRAM 2004 included in the data storage system 2000 may operate as a cache memory, and may provide a space for temporarily storing data in a control operation for the semiconductor package 2003A. When the data storage system 2000 may include the DRAM 2004, the controller 2002 may further include a DRAM controller for controlling the DRAM 2004 in addition to the NAND controller for controlling the semiconductor package 2003A.

The semiconductor package 2003A may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 16. Each of the semiconductor chips 2200 may include gate stack structures 3210 and memory channel structures 3220. Each of the semiconductor chips 2200 may include the semiconductor device described in the aforementioned example embodiment with reference to FIGS. 1 to 9.

In various example embodiments, the connection structure 2400 may be configured as a bonding wire electrically connecting the input/output pad 2210 to the package upper pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In the example embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In the example embodiments, the controller 2002 and the semiconductor chips 2200 may be included in a single package. In an example embodiment, the controller 2002 and the semiconductor chips 2200 may be mounted on an interposer substrate different from the main board 2001, and the controller 2002 and the semiconductor chips 2200 may be connected to each other by interconnection formed on the interposer substrate.

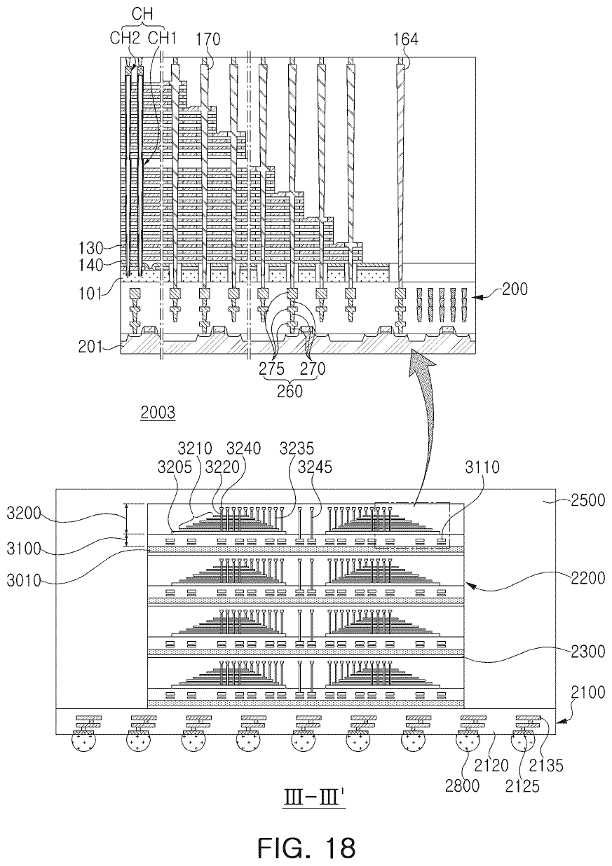

FIG. 18 is a cross-sectional view illustrating a semiconductor package according to an example embodiment, illustrating an example embodiment of the semiconductor package 2003 in FIG. 17 taken along line III-III′.

Referring to FIG. 18, in the semiconductor package 2003A, the package substrate 2100 may be implemented as a printed circuit substrate. The package substrate 2100 may include a package substrate body portion 2120, package upper pads 2130 disposed on an upper surface of the package substrate body portion 2120 (see FIG. 17), lower pads 2125 disposed on the lower surface of the package substrate body portion 2120 or exposed through the lower surface, and internal interconnections 2135 electrically connecting the package upper pads 2130 to the lower pads 2125 in the package substrate body portion 2120. The lower pads 2125 may be connected to the interconnection patterns 2005 of the main board 2001 of the data storage system 2000 through the conductive connection portions 2800 as illustrated in FIG. 17.

Each of the semiconductor chips 2200 may include a first structure 3100 and a second structure 3200 stacked in order on the semiconductor substrate 3010 and the semiconductor substrate 3010. The first structure 3100 may include a peripheral circuit region including peripheral interconnections 3110. The second structure 3200 may include a common source line 3205, a gate stack structure 3210 on the common source line 3205, memory channel structures 3220 and isolation regions penetrating the gate stack structure 3210, bit lines 3240 electrically connected to the memory channel structures 3220, and gate contact plugs 3235 electrically connected to wordlines (WL, see FIG. 16) of the gate stack structure 3210. As described above with reference to FIGS. 1 to 9, each of the semiconductor chips 2200 may include a lower interconnection structure and a capacitor structure 200 formed by a dual-damascene process.

Each of the semiconductor chips 2200 may include a through interconnection 3245 electrically connected to peripheral interconnections 3110 of the first structure 3100 and extending into the second structure 3200. The through interconnection 3245 may be disposed on an external side of the gate stack structure 3210 and may be further disposed to penetrate through the gate stack structure 3210. Each of the semiconductor chips 2200 may further include an input/output pad 2210 (see FIG. 17) electrically connected to the peripheral interconnections 3110 of the first structure 3100.

According to the aforementioned example embodiments, by manufacturing the lower interconnection structure and the capacitor structure by the dual-damascene process, a semiconductor device having improved electrical properties and reliability and a data storage system including the same may be provided.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a first semiconductor structure including a substrate, circuit devices on the substrate, a lower interconnection structure electrically connected to the circuit devices, and a capacitor structure on a same level as a level of at least a portion of the lower interconnection structure; and
a second semiconductor structure on the first semiconductor structure and including a plurality of memory cells arranged three-dimensionally,
wherein the lower interconnection structure includes
a lower contact,
a lower line on the lower contact,
an upper contact on the lower line, and
an upper line on the upper contact,
wherein the capacitor structure includes
first electrode structures extending in a first direction and spaced apart from each other in a second direction intersecting the first direction,
second electrode structures positioned alternately alongside the first electrode structures and spaced apart from each other in the second direction, and
dielectric layers between the first electrode structures and the second electrode structures, and
wherein each of the first electrode structures and the second electrode structures includes
a first lower electrode structure and a second lower electrode structure on a same level as a level of at least one of the lower contact and the lower line, and
a first upper electrode structure and a second upper electrode structure on a same level as a level of at least one of the upper contact and the upper line.

2. The semiconductor device of claim 1,
wherein the first upper electrode structure is electrically connected to the upper line through the first lower electrode structure and the upper contact, and
wherein the second upper electrode structure is electrically connected to the upper line through the second lower electrode structure and the upper contact.

3. The semiconductor device of claim 1,
wherein a width of the first upper electrode structure in the first direction and a width of the first upper electrode structure in the second direction decrease toward an upper surface of the first lower electrode structure.

4. The semiconductor device of claim 1,
wherein each of the first electrode structures further includes a first lowermost electrode structure below the first lower electrode structure and on a same level as a level of the lower contact,
wherein each of the second electrode structures further includes a second lowermost electrode structure below the second lower electrode structure and on the same level as a level of the lower contact, and
wherein the first upper electrode structure extends from a same level as a level of an upper surface of the upper line to a same level as a level of a lower surface of the upper contact.

5. The semiconductor device of claim 1,
wherein the first upper electrode structure includes a first upper electrode line and a first upper barrier surrounding a sidewall of the first upper electrode line,
wherein the first lower electrode structure includes a first lower electrode line and a first lower barrier surrounding a sidewall of the first lower electrode line,
wherein the first upper barrier extends from a same level as a level of an upper surface of the upper line to a same level as a level of a lower surface of the upper contact, and
wherein the first lower barrier extends from a same level as a level of an upper surface of the lower line to a same level as a level of a lower surface of the lower contact.

6. The semiconductor device of claim 1,
wherein each of the first electrode structures further includes a first uppermost electrode structure on the first upper electrode structure and on a same level as a level of the upper line,
wherein each of the second electrode structures further includes a second uppermost electrode structure on the second upper electrode structure and on the same level as a level of the upper line, and
wherein the first lower electrode structure extends from a same level as a level of an upper surface of the lower line to a same level as a level of a lower surface of the lower contact.

7. The semiconductor device of claim 6,
wherein the capacitor structure is in a capacitor region,
wherein an interconnection region in which the lower interconnection structure includes a first interconnection region and a second interconnection region on both sides of the capacitor region,
wherein the first interconnection region includes a first upper line having a first potential among the upper lines,
wherein the second interconnection region includes a second upper line having a second potential different from the first potential among the upper lines,
wherein the first upper line is spaced apart from the first uppermost electrode structure by a first distance in the first direction, and
wherein the second upper line is spaced apart from the first uppermost electrode structure by a second distance in the first direction.

8. The semiconductor device of claim 7, wherein the first distance and the second distance are the same.

9. The semiconductor device of claim 7, wherein the first distance is different from second distance.

10. The semiconductor device of claim 7, wherein at least one of the first distance or the second distance is 2.5 um or more.

11. The semiconductor device of claim 1,
wherein the upper line includes an upper conductive layer and an upper line barrier along a side surface and a lower surface of the upper conductive layer,
wherein the upper contact includes an upper contact plug and an upper contact barrier along a side surface and a lower surface of the upper contact plug,
wherein the lower line includes a lower conductive layer and a lower line barrier along a side surface and a lower surface of the lower conductive layer, and
wherein the lower contact includes a lower contact plug and a lower contact barrier along a side surface and a lower surface of the lower contact plug.

12. The semiconductor device of claim 11,
wherein the lower conductive layer is integrated with and in direct contact with the lower contact plug, and
wherein the lower line barrier is integrated with the lower contact barrier.

13. The semiconductor device of claim 12,
wherein the upper conductive layer is integrated with and in direct contact with the upper contact plug, and
wherein the upper line barrier is integrated with the upper contact barrier.

14. The semiconductor device of claim 12, further comprising:
a first bonding structure connected to the lower interconnection structure and a second bonding structure bonded to the first bonding structure,
wherein the first bonding structure includes a first bonding via connected to the lower interconnection structure and a first bonding pad connected to the first bonding via,
wherein the second bonding structure includes a second bonding via and a second bonding pad connected to the second bonding via, and
wherein the first bonding pad and the second bonding pad are bonded to each other.

15. A semiconductor device, comprising:
a substrate including a capacitor region and an interconnection region on both sides of the capacitor region;
a capacitor structure including a first electrode structures extending in a first direction and spaced apart from each other in a second direction intersecting the first direction;
second electrode structures positioned alternately alongside the first electrode structures and spaced apart from each other in the second direction;
dielectric layers between the first electrode structures and the second electrode structures in the capacitor region;
a lower contact;
a lower line on the lower contact;
an upper contact on the lower line; and
an upper line on the upper contact in the interconnection region,
wherein each of the first electrode structures and the second electrode structures includes
a first lower electrode structure and a second lower electrode structure on a same level as a level of the lower contact or the lower line, and
a first upper electrode structure and a second upper electrode structure on the upper contact or the upper line on a same level as a level of the upper line,
wherein the first upper electrode structure includes a first upper electrode line and a first upper barrier surrounding a sidewall of the first upper electrode line,
wherein the first lower electrode structure includes a first lower electrode line and a first lower barrier surrounding a sidewall of the first lower electrode line,
wherein at least one of the first upper barrier or the first lower barrier extends from a same level as a level of an upper surface of the upper line to a same level as a level of a lower surface of the upper contact, or extends from a same level as a level of an upper surface of the lower line to a same level as a level of a lower surface of the lower contact.

16. The semiconductor device of claim 15,
wherein the second upper electrode structure includes a second upper electrode line and a second upper electrode barrier surrounding a sidewall of the second upper electrode line,
wherein the second lower electrode structure includes a second lower electrode line and a second lower electrode barrier surrounding a sidewall of the second lower electrode line,
wherein at least one of the second upper electrode barrier or the second lower electrode barrier extends from the same level as a level of an upper surface of the upper line to the same level as a level of a lower surface of the upper contact, or extends from the same level as a level of an upper surface of the lower line to the same level as a level of a lower surface of the lower contact.

17. The semiconductor device of claim 15,
wherein the upper line includes an upper conductive layer and an upper line barrier along a side surface and a lower surface of the upper conductive layer,
wherein the upper contact includes an upper contact plug and an upper contact barrier along a side surface and a lower surface of the upper contact plug,
wherein the lower line includes a lower conductive layer and a lower line barrier along a side surface and a lower surface of the lower conductive layer, and
wherein the lower contact includes a lower contact plug and a lower contact barrier along a side surface and a lower surface of the lower contact plug.

18. The semiconductor device of claim 17,
wherein the lower conductive layer is integrated with and in direct contact with the lower contact plug,
wherein the lower line barrier is integrated with the lower contact barrier, and
wherein the upper conductive layer is integrated with and in direct contact with the upper contact plug, and
wherein the upper line barrier is integrated with the upper contact barrier.

19. A data storage system, comprising:
a semiconductor storage device including a substrate, circuit devices on the substrate, a lower interconnection structure electrically connected to the circuit devices, and a capacitor structure, memory cells, and an input/output pad connected to the lower interconnection structure; and
a controller electrically connected to the semiconductor storage device through the input/output pad and controlling the semiconductor storage device,
wherein the lower interconnection structure is in an interconnection region, and includes lower contacts on the circuit devices, lower lines on the lower contacts, upper contacts on the lower lines, and upper lines on the upper contacts,
wherein the capacitor structure includes
first electrode structures extending in a first direction and spaced apart from each other in a second direction intersecting the first direction,
second electrode structures positioned alternately alongside the first electrode structures and spaced apart from each other in the second direction, and
dielectric layers between the first electrode structures and the second electrode structures,
wherein each of the first electrode structures and the second electrode structures includes
a first lower electrode structure and a second lower electrode structure on a same level as a level of at least one of the lower contact and the lower line, and
a first upper electrode structure and a second upper electrode structure on a same level as a level of at least one of the upper contact and the upper line.

20. The data storage system of claim 19,
wherein the first upper electrode structure between the upper lines has a line shape extending in the first direction or a plate shape, and
wherein the first upper electrode structure is spaced apart from the upper line in the first direction, and is electrically connected to the upper line through the first lower electrode structure and the upper contact.
